(19) United States
(12) Patent Application Publication
(10) Pub. No.: US 2020/0071220 A1
(43) Pub. Date: Mar. 5, 2020

(54) GLASS MELTING COMPONENT

(71) Applicant: PLANSEE SE, REUTTE (AT)

(72) Inventors: MICHAEL MARK, REUTTE (AT); KARL-HEINZ LEITZ, REUTTE (AT); HANNES TRAXLER, REUTTE (AT)

(21) Appl. No.: 16/610,608

(22) PCT Filed: Apr. 19, 2018
(86) PCT No.: PCT/AT2018/000025

§ 371 Date: Nov. 4, 2019

(30) Foreign Application Priority Data
May 3, 2017 (AT) GM 97/2017

(51) Int. Cl. C03B 5/027; C30B 35/00; C30B 29/20

(52) U.S. Cl. CPC C03B 5/027; C30B 29/20; C30B 35/002

(57) ABSTRACT

A glass melting component for use in a melt includes at least one guide structure for the conveying and/or nucleation of gas bubbles from the melt. The guide structure is present at least on a surface of the glass melting component which faces the melt during use of the glass melting component.

The invention relates to a glass melting component having the features of the preamble of claim 1.

It is known that in the solidification of glass melts, gases dissolved in the melt can appear as gas bubbles in the glass product obtained from the melt. This is generally undesirable since it results in a deterioration in product yield due to an increased number of rejects.

An example which may be mentioned is the growing of sapphire single crystals from a sapphire melt in which gas bubbles can occur in the sapphire crystal to be drawn and thus impair the quality of the crystal.

It is known that glass melting electrodes are susceptible to bubble formation at the melt-glass melting electrode interface, especially at the beginning of their life. Gas bubbles at the electrode surface lead to an increased corrosion rate due to pit corrosion and thus damage the glass melting component, here especially a glass melting electrode.

In the prior art, there are various approaches for countering the problems associated with the occurrence of gas bubbles.

CN105887198 proposes treating a melting tank with vibrations in order to dislodge gas bubbles in this way.

U.S. Pat. No. 4,334,948 discloses an arrangement for growing single crystals, in which subsidiary capillary slits via which gas dissolved in the melt can escape are provided in addition to a main crystal growing slit. Fewer gas bubbles are said to occur in the main crystal growing slit as a result.

Methods or arrangements for decreasing crossing of gas bubbles from the melt into a glass product are thus proposed in the prior art.

It is an object of the invention to provide an improved glass melting component in the use of which a glass product of higher quality can be obtained and/or the glass melting component itself is attacked to a lesser extent by gas bubbles.

This object is achieved by a glass melting component having the features of claim 1. Preferred embodiments are indicated in the dependent claims.

The presence of at least one guide structure for nucleation and/or conveying of gas bubbles from the melt on a surface of the glass melting component facing the melt during use of the glass melting component results in
crossing of gas bubbles into a glass product being prevented or decreased and/or
gas bubbles being diverted into regions which are not critical for the quality of the glass product and/or
a residence time of gas bubbles at the glass melting component being decreased.

The at least one guide structure is configured as raised region or depression having a pronounced longitudinal extension. In other words, the guide structure can be configured as positive shape projecting from the surface (raised region) or as groove or furrow (as negative shape or depression).

It can also be provided for guide structures configured as depression and guide structures configured as raised region to be present on the glass melting component.

The guide structure is not only present at points, but instead extends along sections of straight lines and/or sections of curves.

The guide structure can very well consist of discrete dot-like individual structures which are arranged along said sections of straight lines and/or curves.

However, the guide structure is preferably configured as continuous longitudinal raised region or as continuous depression.

The at least one guide structure brings about the following effects which are advantageous for control of the gas bubbles:
The guide structure firstly initiates bubble formation for gas dissolved in the melt, that is to say it acts as nucleus. A gas dissolved in the melt is thus transferred in gas bubbles to defined places.
The guide structure brings about “pinning”, i.e. a holding in position of gas bubbles. This creates the opportunity of conveying the resulting gas bubbles in a targeted manner to the corresponding surface of the glass melting component.
The guide structure assists, by means of the ordered geometric structure, coalescence (combining) of small bubbles to form large bubbles. Above a critical size, the latter ascend along the guide structure because of their buoyancy and are thus removed from the melt.

The applicant has recognized that suitable structuring of the surface of a glass melting component makes it possible to obtain a glass product having fewer defects than when using a glass melting component having an unstructured, smooth surface.

The advantageous effects will now be discussed in more detail.

The guide structure configured as raised region or depression on the surface of the glass melting component brings about heterogeneous nucleation.

Whereas the place and point in time of the formation of gas bubbles in melts is not predictable in the prior art, the invention makes the formation of gas bubbles in melts controllable.

The “pinning” or holding in position of gas bubbles makes it possible, for example, to convey gas bubbles by means of the buoyancy acting on the gas bubbles into regions of the glass melting component in which crossing of gas bubbles into the glass product is not critical and/or in which presence of gas bubbles on the glass melting component is not critical.

The coalescence-promoting action of the guide structure is particularly advantageous for separating gas bubbles more quickly from the glass melting component and thus minimizing the abovementioned corrosive damage to the glass melting component.

It can be provided for a guide structure to have an essentially rectangular cross section.

It is also possible for a guide structure to have a cross section which essentially has the shape of a segment of a circle.

It is also possible for a guide structure to have an essentially triangular cross section. Other polygonal cross sections or cross sections having the shape of sections of a curve are also conceivable.

The guide structure preferably has a depth or height in the range from 10 μm to 1000 μm. What is meant here is that a point of inflection of the respective profile in the cross section projects from 10 μm to 1000 μm from the surface of the glass melting component or (for the case of configuration as depression, i.e. as negative structure) goes from 10 μm to 1000 μm into the surface of the glass melting component. The depth or height is more preferably in the range from 20 μm to 500 μm, particularly preferably from 20 μm to 300 μm.

The guide structure preferably has a width in the range from 10 μm to 1000 μm. For the purposes of the present invention, the width is the projected dimension perpendicular to the longitudinal extension of the guide structure. The width is preferably in the range from 20 μm to 300 μm.

It has been shown that when the dimensions of the guide structures are too small, these guide structures are not reacted to by gas bubbles, i.e. gas bubbles cannot be pinned and guided at guide structures which are too small. Experiments have shown that a depth or height and the width should be in the range from 0.1 of a bubble diameter to 10 times a bubble diameter in order to be able to pin and guide gas bubbles at the guide structure. The guide structure preferably has, in a position intended for use of the glass melting component, an inclination relative to the horizontal in the range from 5° to 85°, preferably from 40° to 80°, particularly preferably from 50° to 70°.

This results in gas bubbles nucleated on and adhering to the guide structure being able to be transported away particularly well by buoyancy. In experiments, 60° has been found to be particularly suitable.

In the case of glass melting components having a large area, e.g. plate-like glass melting components, the guide structure is advantageously oriented so that the guide structure runs upward from a middle region of the glass melting component in the direction of an outer edge of the glass melting component. Here, it can be provided for two groups of guide structures to run from the middle region of the glass melting component in the direction of the lateral outer edges of the glass melting component. For the purposes of the present invention, lateral outer edges are any boundaries of the glass melting component which run essentially parallel to the vertical in the installed position of the glass melting component. The above-described arrangement having two groups of guide structures which point outward and upward from a middle region enables, in the case of sheet-like glass components, gas bubbles to be conveyed particularly quickly to an edge of the glass melting component. Since use of sheet-like glass melting components generally gives likewise sheet-like glass products, the advantageous arrangement of the guide structures results in the glass product produced being free of gas inclusions except for the margins. It is particularly advantageous for the guide structures to extend essentially mirror-symmetrically outward from a middle region of the glass melting component since in this way gas bubbles can be carried away in an outward direction along the shortest distance.

In the case of cylindrical glass melting components, the guide structure can follow a screw-like path along the surface. The inclination of the guide structure relative to the horizontal is then the pitch of a guide structure running in a screw-like manner along the surface.

Preference is given to a plurality of essentially parallel guide structures being present on the glass melting component.

The guide structures then run in sets of parallel sections of straight lines or curves.

The guide structures can be introduced by means of various processing methods. In an additive process, additional material is applied to the surface of the glass melting component so as to form a raised region. Examples of additive processes are selective laser melting (SLM) or buildup welding.

An example of a subtractive process is a cutting machining process such as milling.

Structuring by means of pulsed lasers, in particular ultrashort pulsed lasers, is likewise of importance.

Thus, thermal and/or mechanical processes are conceivable.

The at least one guide structure is preferably introduced by mechanical processing. For example, introduction by means of milling is possible.

Structuring by means of a needle, needling, scoring, cutting or the like is also conceivable. As an alternative or in addition, the at least one guide structure can have been introduced by means of thermal and/or chemical treatment. Examples which may be mentioned are laser treatment or etching.

The glass melting component is preferably composed of a refractory metal or a refractory metal alloy.

For the purposes of the present invention, refractory metals are the metals of group 4 (titanium, zirconium and hafnium), group 5 (vanadium, niobium, tantalum) and group 6 (chromium, molybdenum, tungsten) of the Periodic Table plus rhenium. Refractory metal alloys are, for the present purposes, alloys containing at least 50 at. % of the element concerned. These materials have, inter alia, excellent dimensional stability at high use temperatures and are chemically resistant to many melts. Molybdenum and molybdenum alloys have, for instance, a very high resistance to many glass melts.

For the purposes of the present patent application, glass melts are melts of oxidic materials such as siliceous glasses (for example fused silica), borate glasses (for example borosilicate glasses) and also melts of aluminum oxide.

For the purposes of the present patent application, glass melting components are components which are intended for use in contact with glass melts.

These include, for example, glass melting electrodes, tank linings in glass production or melting crucibles. In particular, facilities for the production of fused silica or sapphire crystals are also included. These are, for instance, die packs for drawing flat sapphire crystals.

In the production of sapphire (single) crystals, a crucible is usually charged with aluminum oxide (Al₂O₃) and the aluminum oxide is heated in the crucible to its melting point of about 2050° C. in a furnace. The further process steps differ depending on how the sapphire crystal is drawn and taken from the molten aluminum oxide. Processes used are, for example, the Kyropoulos process, the heat exchanger method (HEM) or the EFG (edge-defined film-fed growth) process.

The present invention is of particular interest for application to glass melting components in the EFG process. In the EFG process, ribbon-shaped or rod-like sapphire crystals are drawn from an aluminum oxide melt. In addition to the melting crucible, a shaping structure, referred to as the die pack, is necessary in order to grow crystals having profile-like shapes. Die packs generally consist of stacked molybdenum sheets, with the sheets being closely spaced (typically 0.5 mm). At about 2050° C., the Al₂O₃ melt is conveyed by capillary action along the narrow slits between the metal sheets and drawn upward. An important quality criterion for such sapphire ribbons is that they have virtually no foreign inclusions in the crystal, in particular no gas bubble inclusions. Gas bubbles can be formed in the melt by reactions with the crucible, but also get into the melt via the process gas atmosphere or via fresh raw material. In the usual growing method, gas bubble inclusions of various sizes occur randomly and at any positions in the crystal ribbons grown.

The random distribution of such defects in the crystal frequently leads to the ribbons not being able to be processed further. This rejection of material is all the more critical, the broader the sapphire ribbons drawn.

The present invention solves this problem of the random distribution of gas bubble inclusions within sapphire ribbons. Gas bubbles that arise, regardless of their origin, are firstly pinned to the metal sheets of the die pack by the guide structure within the die pack and are subsequently discharged at the edge of the individual metal sheets by the guide structure. Even when gas bubbles go over from there (i.e. from the edge) into the crystal ribbon, this is not critical since the crystal ribbon is trimmed. Thus, the yield of the sapphire single crystal can be increased significantly by means of the invention. The glass melting components in the sense of the invention are in this application the metal sheets of the die pack.

The invention can be applied to numerous other glass melting components. On glass melting electrodes, gas bubbles, for instance, can be collected and carried away by a screw-like guide structure. Due to collection of the gas bubbles on the guide structure, the gas bubbles are enlarged by combination (coalescence) and become detached more quickly from the component by the correspondingly greater buoyancy. As a result, the gas bubbles are passed with greater probability than without the guide structure from the melt into the atmosphere and pit corrosion is reduced.

The invention is illustrated below by means of figures. The figures show:

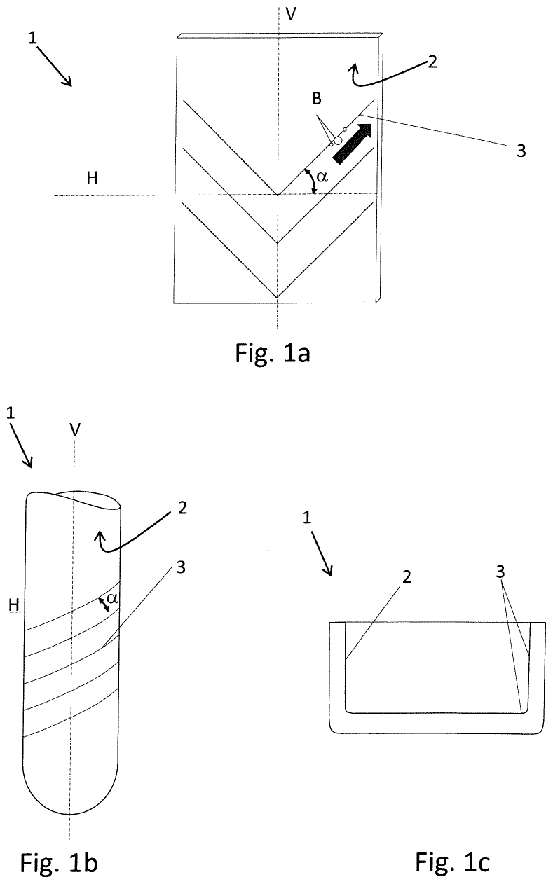

FIG. 1a-c glass melting components in various working examples

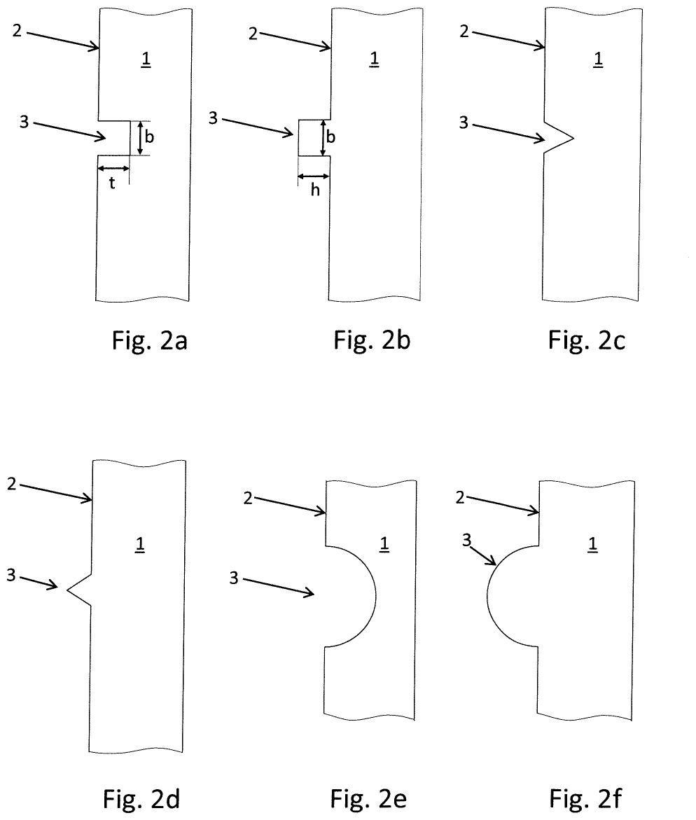

FIG. 2a-f details (schematic) of guide structures

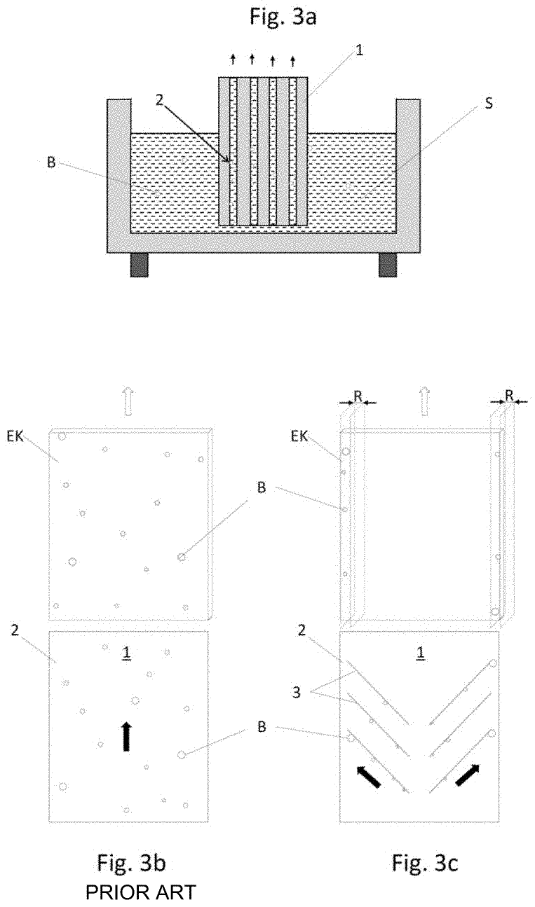

FIG. 3a schematically a plant for producing sapphire single crystals by the EFG process

FIG. 3b a glass melting component according to the prior art

FIG. 3c a working example of a glass melting component having a guide structure

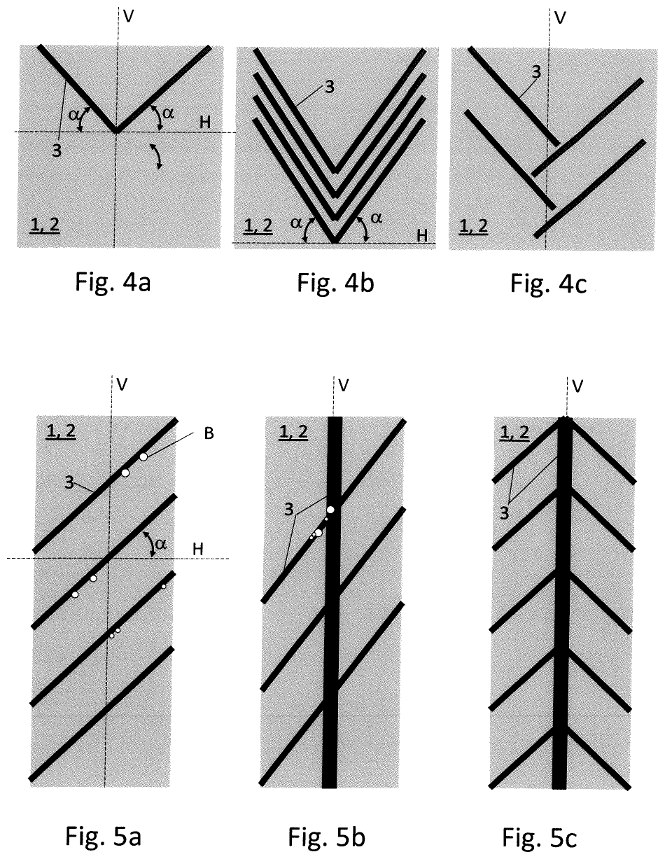

FIG. 4a-4c variants of guide structures on sheet-like glass melting components

FIG. 5a-5c variants of guide structures on cylindrical glass melting components

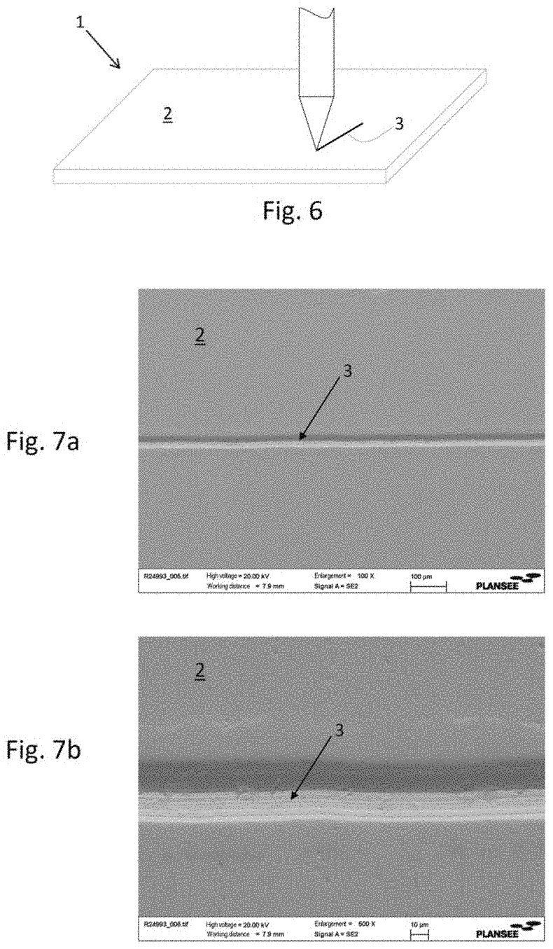

FIG. 6 schematic depiction of introduction of a guide structure

FIGS. 7a and 7b scanning electron micrographs of a surface having a guide structure

FIG. 1a shows a glass melting component 1 having a surface 2 which faces a melt during use of the glass melting component 1, in plan view. On the surface 2 facing the melt there are guide structures 3 for the guiding and/or nucleation of gas bubbles from the melt. The glass melting component 1 in the present case has a plate-like shape. It can be, for example, a metal sheet of a die pack as described above. The orientation of the glass melting component 1 during use is denoted by a vertical V and a horizontal H.

The guide structures 3 are arranged in a herringbone fashion in the present working example. They run at an angle α relative to the horizontal H from a middle region of the glass melting component 1 upward to the outside. The indications of directions are based on an installed position of the glass melting component 1 during use.

The guide structures 3 are configured as depression (as concave or negative structure) on the surface 2 facing the melt. As an alternative, the guide structure 3 can be configured as raised region (as convex or positive structure).

Heterogeneous nucleation results in formation of gas bubbles on the guide structure 3 and these largely remain adhering to the guide structure 3. The orientation of the guide structures 3 at an angle α relative to the horizontal H results in gas bubbles B on the guide structures 3 being conveyed upward by buoyancy (indicated by the black block arrow) to the edges of the glass melting component 1. The angle α is preferably about 60°.

In FIG. 1b, the glass melting component 1 is configured as glass melting electrode. The guide structures 3 in this case run in a screw-like manner at an angle α relative to the horizontal H to the surface 2 of the glass melting component 1. Gas bubbles form and collect at the guide structure 3. As a result of collection of the gas bubbles at the guide structure 3, the gas bubbles combine to form larger bubbles and become detached more quickly from the glass melting component 1, here the glass melting electrode, due to the higher buoyancy.

FIG. 1c shows glass melting component 1 as crucible or melting tank. Here too, guide structures 3 can be present on the surface 2 of the glass melting component 1 which faces the melt. The effect of the guide structures here is primarily nucleation of gas bubbles. Thus, outgassing of a melt in the glass melting component 1 is thus accelerated.

FIGS. 2a to 2f schematically show glass melting components 1 having various configurations of guide structures 3 in cross section.

FIG. 2a shows a guide structure 3 as depression having an essentially rectangular cross section on the surface 2 of the glass melting component 1 which faces the melt.

FIG. 2b shows a guide structure 3 as raised region having an essentially rectangular cross section on the surface 2 of the glass melting component 1 which faces the melt.

FIG. 2c shows a guide structure 3 as depression having an essentially triangular cross section on the surface 2 of the glass melting component 1 which faces the melt.

FIG. 2d shows a guide structure 3 as raised region having an essentially triangular cross section on the surface 2 of the glass melting component 1 which faces the melt.

FIG. 2e shows a guide structure 3 as depression having a cross section having the shape of essentially a segment of a circle on the surface 2 of the glass melting component 1 which faces the melt.

FIG. 2f shows a guide structure 3 as raised region having a cross section having the shape of essentially a segment of a circle on the surface 2 of the glass melting component 1 which faces the melt.

The negative forms of the guide structures 3 in FIGS. 2a, 2c and 2e have a depth t which is preferably in the range from 10 μm to 1000 μm, as shown by way of example in FIG. 2a.

The positive forms of the guide structures in FIGS. 2b, 2d and 2f have a height h which is in the range from 10 μm to 1000 μm, as shown by way of example in FIG. 2b. The depth or height is more preferably in the range from 20 μm to 500 μm, particularly preferably from 20 μm to 300 μm.

A width b of the guide structures 3 is indicated by way of example in FIGS. 2a and 2b and is preferably in the range from 10 μm to 1000 μm. The width b is more preferably in the range from 20 μm to 300 μm.

The dimensions in respect of the depth t, the width b and the height h are shown by way of example in FIGS. 2a and 2b and apply analogously to the FIGS. 2c to 2f.

Unlike grooves as can be present on a surface after conventional machining, for example milling or grinding, the guide structures preferably cover significantly less than 10% of the surface. Machining structures from conventional machining, on the other hand, are present over the entire surface.

A further difference of machining structures, for example grooves, from conventional machining is that grooves are essentially uniformly distributed over the entire surface and are frequently oriented along one direction. In addition, the depth or height of the guide structures is significantly greater than roughness values originating from conventional machining. Thus, maximum roughness values Ra of a turned surface are, for example, 1.0 μm while the guide structure preferably has a depth t or height h in the range from 10 μm to 1000 μm. The guide structures are thus at least an order of magnitude larger than tracks of conventional machining.

FIG. 3a schematically shows a plant for producing sapphire single crystals by the EFG process. Here, metal sheets, which generally consist of molybdenum, are dipped at a close spacing into a melt S of Al₂O₃. The arrangement is referred to as die pack. Melt S rises through the capillary gap between the metal sheets and can be drawn off as sapphire single crystal, as indicated by the directional arrows. Gas bubbles B occur in the melt S. The glass melting components 1 in this use example are the individual metal sheets of the die pack arrangement.

FIG. 3b shows a glass melting component 1 in the form of a metal sheet of a die pack arrangement and a single crystal EK according to the prior art obtained with the aid of this component. Gas bubbles B are randomly distributed on the glass melting component 1 at the surface 2 facing the melt, and these are again present randomly distributed over a cross section of the single crystal EK (shown above the glass melting component 1). A single crystal EK having gas bubbles cannot be used.

FIG. 3c, on the other hand, shows a glass melting component 1 in a working example of the invention. Here, guide structures 3 have been produced on the surface 2 of the glass melting component 1, here configured as metal sheet of a die pack arrangement, which faces the melt.

Gas bubbles B collect at the guide structures 3 and are, as indicated above, conveyed upward and outward. The arrangement and number of the guide structures 3 is purely schematic.

Absolutely no gas bubbles B are present in the single crystal EK (shown above the glass melting component 1) obtained using the glass melting component 1 of this working example, or gas bubbles B are restricted to a peripheral region R. This peripheral region R can be trimmed off, so that the yield of single crystal EK is significantly increased compared to the prior art when using a glass melting component 1 according to the invention.

FIGS. 4a to 4c show different variants of the arrangements of guide structures 3 on the surface 2 of sheet-like glass melting components 1 for the example of a metal sheet of a die pack.

FIG. 4a shows two guide structures 3 which are inclined at an angle α to the horizontal H and run upward and outward.

The variant of FIG. 4b shows two sets of guide structures 3 which are inclined at an angle α to the horizontal H and run upward and outward. The angle α here is greater than in the example of FIG. 4a.

In the example of FIG. 4c, guide structures 3 are offset and overlap in a projection along the vertical H. Due to the overlapping, gas bubbles are collected with a particularly high probability by the guide structures 3.

FIGS. 5a to 5c show different variants of the arrangements of guide structures 3 on the surface 2 of an essentially cylindrical glass melting component 1 for the example of a glass melting electrode.

In the example of FIG. 5a, the guide structures 3 run in a screw-like manner at an angle α to the horizontal along the surface 2 of the glass melting electrode.

In the example shown in FIG. 5b, a riser channel is provided in addition to a screw-like guide structure 3. The riser channel can be configured as groove or furrow essentially parallel to the vertical V along the surface 2. Gas bubbles which are guided by the guide structure 3 to the riser channel become detached from the guide structure 3 there and escape via the riser channel. In this way, the gas bubbles are removed particularly quickly from the glass melting component 1, here glass melting electrode. The guide structures 3 themselves can run in a screw-like manner along a single screw curve or, as shown in the variant in FIG. 5c, along various partial screw tracks which can have an opposite handedness. Other courses along essentially continuous curves, preferably continuously ascending curves, are also possible.

The number of guide structures 3 shown in all the figures is purely illustrative. The actual number depends on the dimensions of the glass melting component 1. To name an example, from one to ten guide structures 3 could be present on a metal sheet having typical dimensions of about 100×100 mm for a die pack. A balanced ratio of the number of guide structures and their spacing is advantageous. Both can be determined by experiment. An excessively close arrangement brings no additional benefits while in the case of spacings which are too large, gas bubbles may no longer be able to be collected.

In the case of the example of the glass melting electrode in which the guide structure 3 can run continuously along a screw curve, the individual tracks of the guide structures can, for example, be 1-2 cm apart.

The spacing of the guide structures is thus significantly greater than the structure size of the guide structure itself. Here, the term structure size means the width and also height or depth of the guide structures.

FIG. 6 shows a process for producing a guide structure 3 in the surface 2 of a glass melting component 1. Here, the introduction is effected by means of scoring with a scoring needle.

FIGS. 7a and 7b show scanning electron micrographs of a surface 2 having a guide structure 3, with the images differing in respect of the enlargement selected. In the present example, the guide structure 3 was introduced into a molybdenum sheet by needle scoring. It can be seen that the width b of the guide structure 3 is about 30 μm.

The depth of the guide structure is about 15 μm.

1-16. (canceled)

17. A glass melting component for use in a melt, the glass melting component comprising:
a surface of the glass melting component facing the melt during use of the glass melting component; and
at least one guide structure disposed on said surface facing the melt for at least one of conveying or nucleation of gas bubbles from the melt.

18. The glass melting component according to claim 17, wherein said at least one guide structure is a raised region on said surface facing the melt.

19. The glass melting component according to claim 17, wherein said at least one guide structure is a depression on said surface facing the melt.

20. The glass melting component according to claim 17, wherein said at least one guide structure includes guide structures configured as depressions and guide structures configured as raised regions.

21. The glass melting component according to claim 17, wherein said at least one guide structure has a substantially rectangular cross section.

22. The glass melting component according to claim 17, wherein said at least one guide structure has a cross section having substantially a shape of a segment of a circle.

23. The glass melting component according to claim 17, wherein said at least one guide structure has a depth or a height in a range of from 10 μm to 1000 μm.

24. The glass melting component according to claim 17, wherein said at least one guide structure has a width in a range of from 10 μm to 1000 μm.

25. The glass melting component according to claim 17, wherein said at least one guide structure has an inclination of from 5° to 85° relative to the horizontal in a position of the glass melting component intended for use.

26. The glass melting component according to claim 17, wherein said at least one guide structure has an inclination of from 40° to 80° relative to the horizontal in a position of the glass melting component intended for use.

27. The glass melting component according to claim 17, wherein said at least one guide structure has an inclination of from 50° to 70° relative to the horizontal in a position of the glass melting component intended for use.

28. The glass melting component according to claim 17, wherein said at least one guide structure includes a plurality of substantially parallel guide structures disposed on the glass melting component.

29. The glass melting component according to claim 17, wherein said at least one guide structure is mechanically worked into said surface facing the melt.

30. The glass melting component according to claim 17, wherein said at least one guide structure is at least one of thermally or chemically formed into said surface facing the melt.

31. The glass melting component according to claim 17, wherein the glass melting component is composed of refractory metal or of a refractory metal alloy.

32. The glass melting component according to claim 17, wherein the glass melting component is a metal sheet of a die pack for growing sapphire single crystals.

33. The glass melting component according to claim 17, wherein the glass melting component is a glass melting electrode.

34. The glass melting component according to claim 17, wherein the glass melting component is a crucible or a melting tank.
